(19) United States
(12) Patent Application Publication
(10) Pub. No.: US 2010/0059729 A1
(43) Pub. Date: Mar. 11, 2010

(54) Apparatus and method for memory

(75) Inventor: Stephen Hudgens, Santa Clara, CA (US)

Correspondence Address: Ovonyx, Inc, 2956 Waterview Drive, Rochester Hills, MI, 48309, US

(73) Assignee: Ovonyx, Inc.

(21) Appl. No.: 12/283,113

(22) Filed: Sep. 9, 2008

(51) Int. Cl. H01L 47/00; H01L 21/00

(52) U.S. Cl. 257/2; 257/3; 438/102; 257/E47.001; 257/E21.001

(57) ABSTRACT

A programmable resistance memory includes a volume of programmable resistance material formed between and coupled to two electrodes. The volume of programmable resistance material includes a region of enhanced programmability that is positioned to maximize the effect of a programming current. The region of enhanced programmability is positioned at a distance from regions of high thermal conductivity, such as areas in close proximity to electrodes.

### CROSS-REFERENCE TO RELATED APPLICATIONS

### FIELD OF INVENTION

This invention relates to electronic memory circuits.

### BACKGROUND OF THE INVENTION

As semiconductor memories approach limits beyond which they will no longer be able to produce the density/cost/performance improvements so famously set forth in Moore's law, a host of memory technologies are being investigated as potential replacements for conventional silicon complementary metal oxide semiconductor (CMOS) integrated circuit memories. Among the technologies being investigated are phase change memory technologies. Phase-change memory arrays are based upon memory elements that switch among two material phases, or gradations thereof, to exhibit corresponding distinct electrical characteristics. Alloys of elements of group VI of the periodic table, such as Te, S or Se, referred to as chalcogenides or chalcogenic materials, can be used advantageously in phase change memory cells. In the chalcogenides, the resistivity varies by two or more orders of magnitude when the material passes from the amorphous (more resistive) phase to the crystalline (more conductive) phase, and vice versa. Further, the resistivity of the chalcogenide materials generally depend on the temperature with the amorphous state generally being more temperature dependent that the crystalline state.

A chalcogenide memory device may utilize the wide range of resistance values available for the material as the basis of memory operation. Each resistance value corresponds to a distinct structural state of the chalcogenide material and one or more of the states can be selected and used to define operation memory states. Chalcogenide materials exhibit a crystalline state, or phase, as well as an amorphous state, or phase. Different structural states of a chalcogenide material differ with respect to the relative proportions of crystalline and amorphous phase in a given volume or region of chalcogenide material. The range of resistance values is generally bounded by a set state and a reset state of the chalcogenide material. By convention, the set state is a low resistance structural state whose electrical properties are primarily controlled by the crystalline portion of the chalcogenide material and the reset state is a high resistance structural state whose electrical properties are primarily controlled by the amorphous portion of the chalcogenide material.

Phase change may be induced by increasing the temperature locally. For some alloys, below 150° C., both of the phases are stable. Above 200° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C.) and then cool it off rapidly, i.e. quench. From the electrical standpoint, it is possible to reach the crystallization and melting temperatures by causing a current to flow through a crystalline resistive element that heats the chalcogenic material by the Joule effect.

Each memory state of a chalcogenide memory material corresponds to a distinct range of resistance values and each memory resistance value range signifies unique informational content. Operationally, the chalcogenide material can be programmed into a particular memory state by providing an electric current pulse of an appropriate amplitude and duration to transform the chalcogenide material into the structural state having the desired resistance. By controlling the amount of energy provided to the chalcogenide material, it is possible to control the relative proportions of crystalline and amorphous phase regions within a volume of the material and to thereby control the structural (and corresponding memory) state of the chalcogenide material to store information.

Each memory state can be programmed by providing the current pulse characteristics of the state and each state can be identified, or “read”, in a non-destructive fashion by measuring the resistance. Programming among the different states is fully reversible and the memory devices can be written and read over a virtually unlimited number of cycles to provide robust and reliable operation. The variable resistance memory functionality of chalcogenide materials is currently being exploited in the OUM (Ovonic Universal (or Unified) Memory) devices that are beginning to appear on the market. Basic principles and operation of OUM type devices are presented, for example, in U.S. Pat. Nos. 6,859,390; 6,774,387; 6,687,153; and 6,314,014; the disclosures of which are incorporated by reference herein, as well as in several journal articles including, “Low Field Amorphous State Resistance and Threshold Voltage Drift in Chalcogenide Materials,” published in EE transactions on Electron Devices, vol. 51, p. 714-719 (2004) by Pirovana et al.; and “Morphing Memory,” published in IEEE Spectrum, vol. 167, p. 363-364 (2005) by Weiss.

The behavior (including switching, memory, and accumulation) and chemical compositions of chalcogenide materials have been described, for example, in the following U.S. Pat. Nos. 6,671,710; 6,714,954; 6,087,674; 5,166,758; 5,296,716; 5,536,947; 5,596,522; 5,825,046; 5,687,112; 5,912,839; and 3,530,441, the disclosures of which are hereby incorporated by reference. These references present proposed mechanisms that govern the behavior of chalcogenide materials. The references also describe the structural transformations from the crystalline state to the amorphous state (and vice versa) via a series of partially crystalline states in which the relative proportions of crystalline and amorphous regions vary during the operation of electrical and optical programming of chalcogenide materials.

A wide range of chalcogenide compositions has been investigated in an effort to optimize the performance characteristics of chalcogenic devices. Chalcogenide materials generally include a chalcogen element and one or more chemical or structural modifying elements. The chalcogen element (e.g. Te, Se, S) is selected from column VI of the periodic table and the modifying elements may be selected, for example, from column III (e.g. Ga, Al, In), column IV (e.g. Si, Ge, Sn), or column V (e.g. P, As, Sb) of the periodic table. The role of modifying elements includes providing points of branching or cross-linking between chains comprising the chalcogen element. Column IV modifiers can function as tetracoordinate modifiers that include two coordinate positions within a chalcogenide chain and two coordinate positions that permit branching or crosslinking away from the chalcogenide chain. Column III and V modifiers can function as tricoordinate modifiers that include two coordinate positions within a chalcogenide chain and one coordinate position that permits branching or crosslinking away from the chalcogenide chain. Embodiments in accordance with the principles of the present invention may include binary, ternary, quaternary, and higher order chalcogenide alloys. Examples of chalcogenide materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. Chalcogenide materials may be deposited with a reactive sputtering process with gasses such as N2 or O2: forming a chalcogenide nitride, or oxide, for example and chalcogenide may be modified by an ion implantation or other process.

Early work in chalcogenide devices demonstrated electrical switching behavior in which switching from an “off” resistive state to an “on” conductive state was induced upon application of a voltage at or above the threshold voltage of the active chalcogenide material. This effect is the basis of the Ovonic Threshold Switch (OTS) and remains an important practical feature of chalcogenide materials. The OTS provides highly reproducible switching at ultrafast switching speeds. Basic principles and operational features of the OTS are presented, for example, in U.S. Pat. Nos. 3,271,591; 5,543,737; 5,694,146; and 5,757,446; the disclosures of which are hereby incorporated by reference, as well as in several journal articles including “Reversible Electrical Switching Phenomena in Disordered Structures,” Physical Review Letters, vol. 21, p. 1450-1453 (1969) by S. R. Ovshinsky; “Amorphous Semiconductors for Switching, Memory, and Imaging Applications,” IEEE Transactions on Electron Devices, vol. ED-20, p. 91-105 (1973) by S. R. Ovshinsky and H. Fritzsche; the disclosures of which are hereby incorporated by reference. Three-terminal OTS devices are disclosed, for example, in U.S. Pat. Nos. 6,969,867 and 6,967,344; the disclosures of which are hereby incorporated by reference.

Although highly efficient and cost effective, process methods and device structures that improve the performance of phase change memories would be highly desirable.

### SUMMARY OF THE INVENTION

A programmable resistance memory cell in accordance with the principles of the present invention includes a volume of programmable resistance material formed between and coupled to two electrodes. The volume of programmable resistance material includes a region of enhanced programmability that is positioned to maximize the effect of a programming current. In an illustrative embodiment, the region of enhanced programmability is positioned at a distance from regions of high thermal conductivity, such as areas in close proximity to electrodes. The programmable resistance material may be, for example, phase change material, such as chalcogenide material. Such enhanced programmability may be implemented as preferential resetting, for example.

In a phase change material embodiment, the phase change material may include a region of enhanced phase change that is positioned at a distance from either electrode. The region of enhanced phase change may be created by modifying the “unprogrammed resistance” profile of the volume of phase change material. A region of enhanced phase change may also be created by modifying the melting point of phase change material within the volume. In particular, a region of enhanced phase change may be created by reducing the melting point of phase change material within the volume. Combinations of lowered melting point and increased resistivity are also contemplated within the scope of the invention. By “unprogrammed resistance” we mean the resistance of the material in its minimal-resistance state. This minimal resistance, “unprogrammed resistance,” state may also be referred to herein as the SET state. In an illustrative embodiment, the phase change material includes a region of material that exhibits higher resistance than the surrounding phase change material, even in the SET state, and such an enhanced-resistance region is positioned at a distance from either electrode: midway between electrodes in an illustrative embodiment. The enhanced-resistance region may bisect the current path between the cell's electrodes and, in an illustrative embodiment, may form a disk of enhanced resistance material across a pore of phase change material. Such a disk of enhanced resistance material may be formed by implanting the phase change material to increase the phase change material's resistance. For example, a memory cell including a modified SET resistance profile may be formed by implanting Si⁺, N⁺, N₂⁺, O⁺, or O₂⁺, ions in phase change memory material. Alternatively, a disk of enhanced resistance material may be formed by successively depositing a layer of “base” phase change material, a layer of enhanced-resistance phase change material, then another layer of “base” phase change material in a pore, for example.

However a region of enhanced-resistance is produced, such a region dissipates more energy for a given current flow between a cell's electrodes than surrounding areas of lower resistance. By dissipating more energy, the enhanced-resistance material attains a higher temperature and, therefore, changes phase at lower current levels than surrounding phase change material. In that sense, the enhanced-resistance regions are enhanced programmability regions. Positioning such regions of enhanced programmability at a remove from thermally dissipative elements, such as electrodes, further enhances the programmability of the material, because less thermal energy will be channeled away from the region undergoing a phase change. If, in addition, such a region of enhanced programmability is positioned to “seal off” all current paths between the electrodes, phase change can be limited to the enhanced-programmability region. Use of a confined cell, such as a filled-pore cell, facilitates such a process.

In an illustrative embodiment, the phase change material is confined, in a pore structure situated between two electrodes for example, and the minimal resistance profile of the device exhibits a continuously-variable distribution having a peak in a location at a distance from both electrodes. An electrical resistance distribution in accordance with the principles of the present invention configures a phase change memory cell to concentrate power in a region where it is most effective at changing the phase of a critical portion of device's phase change memory material, thereby reducing the device's power consumption.

A memory that employs a modified SET resistance profile in accordance with the principles of the present invention may be particularly suitable for operation in a variety of electronic devices, including cellular telephones, radio frequency identification devices (RFID), computers (portable and otherwise), solid state drives (SSDs), location devices (e.g., global positioning system (GPS) devices, particularly those that store and update location-specific information), and handheld electronic devices, including personal digital assistants (PDAs), and entertainment devices, such as MP3 players, for example.

### BRIEF DESCRIPTION OF THE DRAWINGS

FIG. 1 is a plot of programming current versus resistance for a programmable resistance memory;

FIG. 2 is a cross-section of a confined-cell programmable resistance memory;

FIGS. 3A through 3D are cross section and corresponding resistivity, power dissipation, and temperature plots for a conventional confined cell programmable resistance memory;

FIGS. 4A through 4D are cross section and corresponding resistivity/melting temperature, power dissipation, and temperature plots for a confined cell programmable resistance memory in accordance with the principles of the present invention;

FIGS. 5A through 5D are cross section and corresponding resistivity, power dissipation, and temperature plots for a confined cell programmable resistance memory in accordance with the principles of the present invention;

FIG. 6 is a plot of ion ranges for an implantation process such as may be employed in producing a programmable resistance memory in accordance with the principles of the present invention;

FIG. 7 is a block diagram of a hierarchical array of programmable resistance memories in accordance with the principles of the present invention; and

FIG. 8 is a conceptual block diagram of an electronic system such as may employ programmable resistance memories in accordance with the principles of the present invention.

### DETAILED DESCRIPTION

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, chemical, and electrical changes may be made without departing from the spirit or scope of the invention. Polarities and types of devices and supplies may be substituted in a manner that would be apparent to one of reasonable skill in the art. Accordingly, the scope of the invention is defined only by reference to the appended claims.

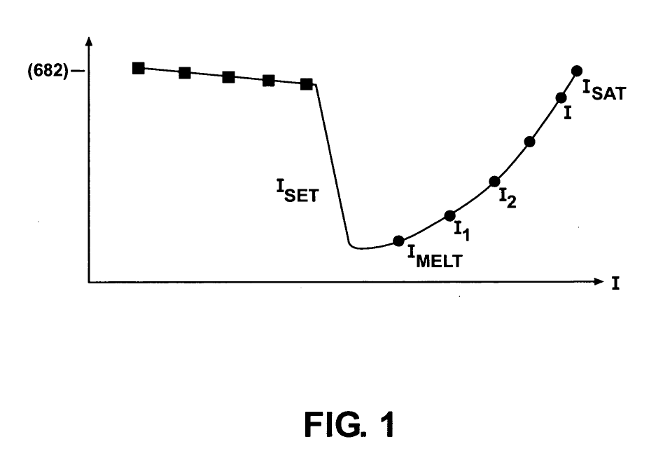

FIG. 1 is a graph of resistance vs. current-pulse amplitude, such as may be produced by operation of a phase change memory cell. The ordinate of the graph represents the electrical resistance across a volume of phase change material as measured at two electrodes in electrical communication through the phase change material. The abscissa represents the various amplitudes of current pulses that may be applied to the phase change device. In this depiction, we assume that the current pulses are of equal duration and similar shape (substantially rectangular). Consequently, current pulse magnitude acts as a proxy for the energy content of a pulse.

At the leftmost extreme of the graph the phase change material exhibits a relatively high resistance of 1 MΩ. Such a resistance is characteristic of a RESET state. A current pulse of amplitude I_{SET} crystallizes a sufficient amount of phase change material to provide a relatively low resistance path from one electrode to another. Current pulses of greater amplitude may be applied to the phase change device in an attempt to increase the resistance of the device. In the illustrative embodiment of FIG. 1, current pulses having magnitudes between that of I_{SET} and I_{MELT} yield insignificant changes in the resistance of the phase change device.

With a current pulse of amplitude I_{MELT}, the energy content of the current pulse is sufficient to melt at least a portion of phase change material. With rapid quenching, the melted phase change material is transformed to an amorphous state. That is, a relatively short duration programming pulse (e.g., on the order of tens of nanoseconds) allows the melted material to cool before significant crystallization of the melted material may occur. As a result, a portion of phase change material in the current path between the electrodes is transformed by the current pulse I_{MELT} to an amorphous state that is characterized by a relatively high electrical resistance. The value of increased resistance selected to define I_{MELT} may be somewhat arbitrary. For the sake of this discussion, a resistance increase from the low, SET, resistance, to 0.5% of the high, RESET, resistance corresponds to the melt resistance, R_{MELT}, and melt current amplitude, I_{MELT}. At the other extreme of amorphization, the saturation resistance is the maximum attainable resistance of the phase change material and the saturation current, I_{SAT}, is the corresponding current pulse amplitude.

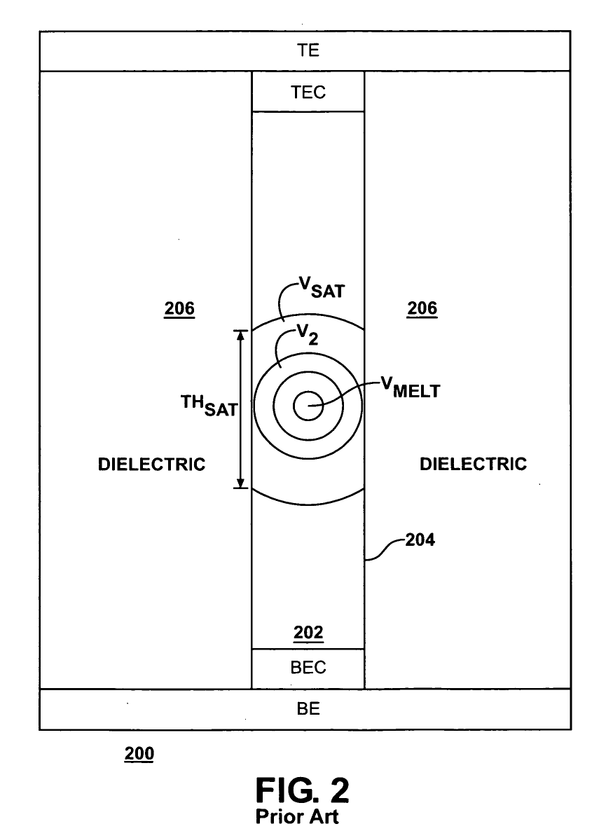

FIG. 2 is a cross section of a conventional confined-cell phase change memory device 200. In this illustrative embodiment a volume of phase change material 202 fills a pore 204 that has been formed in dielectric material 206. Top TE and bottom BE electrodes provide current to the phase change material 202 to alter or sense the phase of material 202 within the pore 204 and to thereby write to or read from the device 200. Top and bottom electrode contacts TEC, BEC, are high thermal-resistivity elements employed to reduce the thermal conductivity at the interface between the phase change material 202 and the electrodes. In an illustrative embodiment, the phase change material is Ge₂Sb₂Te₂, which, in its hexagonal close-packed (HCP) phase exhibits a thermal conductivity of 1 W/m K. The electrode contact material, which may be TiAlN or TiSiN, for example, although far less conductive than the electrode material (aluminum, for example), exhibits a thermal conductivity that may still be, at 15 W/mK, more than an order of magnitude greater than that of the HCP Ge₂Sb₂Te₂.

The assumption that the volume of phase change material 202 is initially in a crystalline phase, corresponding to a SET state, is built in to FIG. 2. Such a state may be established by application of a current I_{SET}, as previously described in the discussion related to FIG. 1. Current pulses of different magnitudes: I_{MELT}, I₁, I₂, and I_{SAT}, yield respective volumes of melted phase change material V_{MELT}, V₁, V₂, and V_{SAT}. As is known in the art, if the melted phase change material is rapidly cooled below the material's crystallization temperature, the volume of melted material is transformed to an amorphous phase. Resistances R_{MELT}, R₁, R₂, and R_{SAT}, which respectively correspond to volumes V_{MELT}, V₁, V₂, and V_{SAT} of amorphized material are associated with their corresponding melted volumes.

As indicated in FIG. 2, the amorphous material tends to melt (and amorphize) at a distance from either electrode TE, BE. Because the electrodes TE, BE are relatively good thermal conductors, joule heat generated proximate the electrodes is channeled away from the phase change material. As described in the discussion related to FIG. 1, the crystalline phase change material 202 is, in contrast to the electrodes BE, TE, a relatively good thermal insulator. Consequently, joule heating that takes place in the center of the pore (substantially mid-way between the electrodes in this illustrative embodiment) is directed towards melting the phase change material 202 in a relatively efficient manner. In contrast, the electrodes TE, BE, being more thermally conductive than the phase change material, conduct heat away from the phase change material, thereby inhibiting the melting of phase change material in their vicinity.

The result is a tendency for phase change material to melt, as indicated in FIG. 2, in the form of a sphere within the pore 204 centered equidistant from the electrodes BE, TE. This analysis also assumes that the surrounding dielectric material 206 exhibits a higher thermal conductivity than the phase change material 202 in its crystalline state. As the volume of melted (and quenched) phase change material increases with increasing pulse amplitude, the resistance across the cell increases. With increasing pulse amplitude, the resistance between electrodes continues to increase, even after amorphized material expands to contact the surrounding walls of the pore (see, for example, the amorphized sphere having a volume V₂ that yields resistance R₂). The volume of amorphized material will increase until the minimal thickness of amorphized material reaches a point where the cell reaches saturation resistance. We will refer herein to the minimal thickness of amorphized material that yields saturation resistance as the “saturation thickness,” TH_{SAT}.

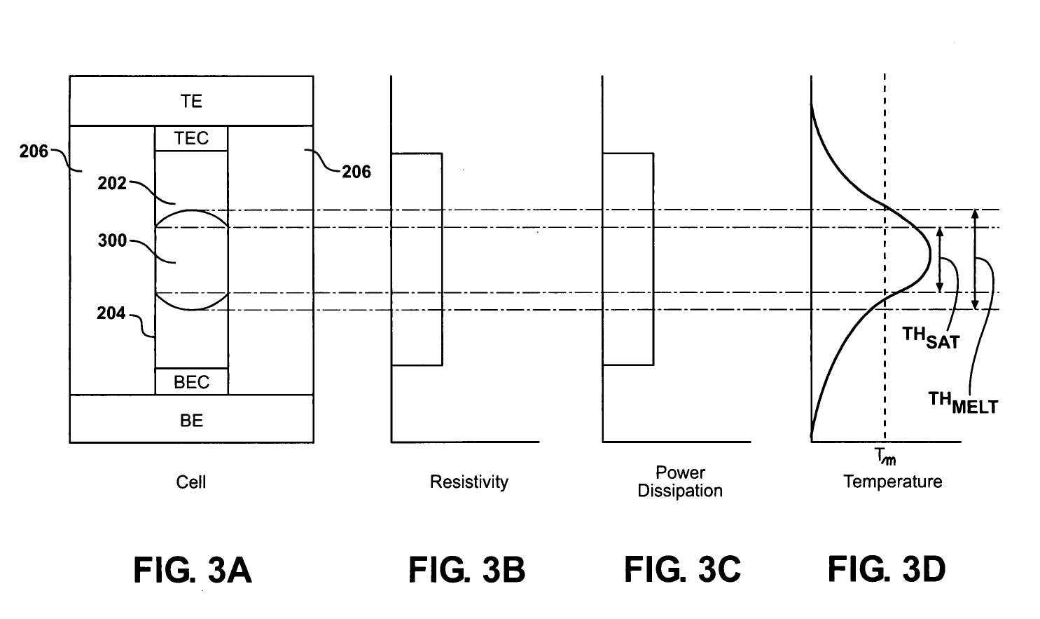

FIGS. 3A, 3B, 3C and 3D are graphical representations, respectively, of an amorphization profile of a confined-cell phase change memory, of the corresponding resistivity of phase change material within the pore 204, of the corresponding power dissipation during programming of phase change material 202 within the pore 204, and of the corresponding temperature within the pore 204. In this illustrative embodiment the cell has been programmed to the RESET state by raising the temperature of a volume of phase change material to the melting temperature Tm of the phase change material and cooling the melted material rapidly to thereby quench the material in the amorphous state. The volume of material thus-transformed may be referred to herein as the programmed volume 300. The programmed volume 300 exhibits a profile that includes a minimal vertical thickness TH_{SAT}, which ensures that the resistance of the phase change cell, as measured between the two contacts, TEC and BEC, equals or exceeds the saturation resistance of the cell.

The resistivity profile of FIG. 3B illustrates the SET resistivity of the phase change material 202. In this illustrative embodiment, all the phase-change material exhibits the same resistivity. Because the resistivity throughout the phase change material is uniform and the current through the material is uniform, the power dissipation, i²R, is also the uniform throughout the material, as indicated by the straight vertical segment of the curve of FIG. 3C. Although the power dissipation throughout the phase change material is uniform, heat dissipation varies throughout the pore 204, thereby producing the temperature profile of FIG. 3D. In particular, although the top TEC and bottom BEC electrode contacts are typically composed of a material that provides greater thermal insulation than the top and bottom electrodes TE, BE, the top and bottom electrode contacts TEC, BEC are, nevertheless, better thermal conductors than either the dielectric material 206 surrounding the pore 204 or the SET phase change material 202. As a result, a higher-amplitude current pulse is required to melt phase change material that is close to either electrode contact BEC, TEC, and phase change material within the pore 206 at a distance from either electrode melts preferentially.

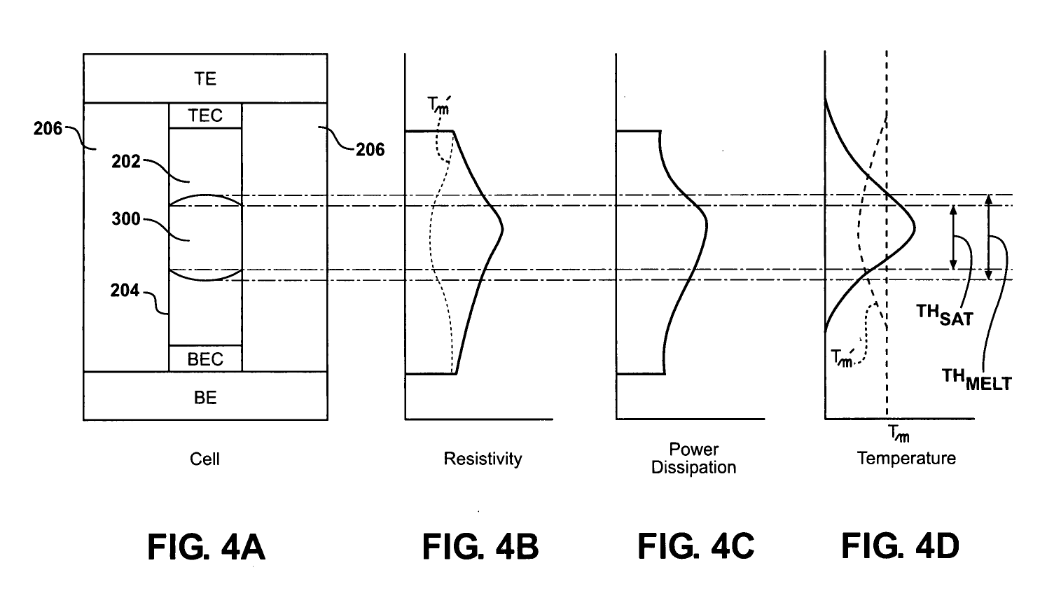

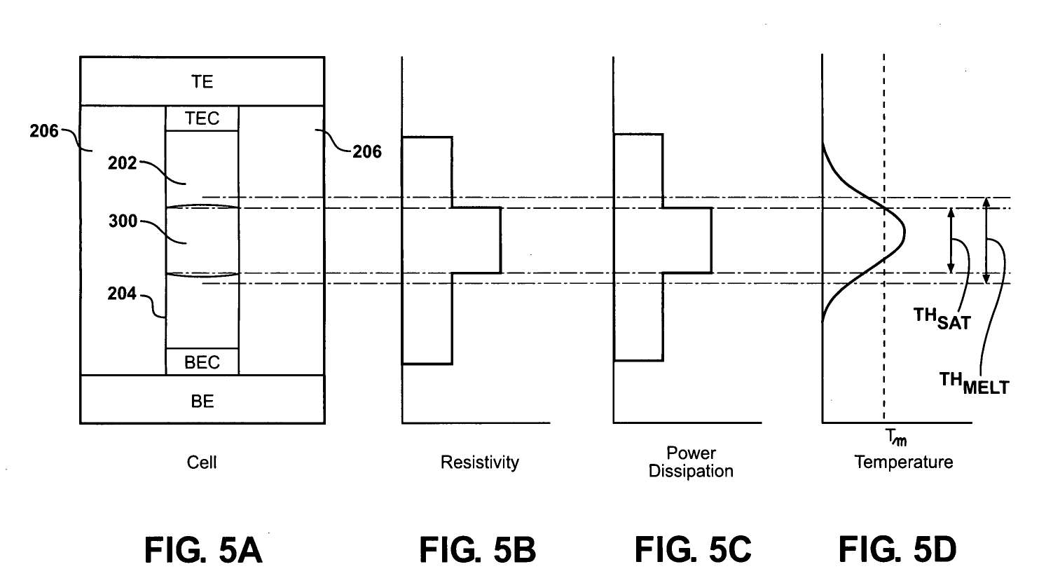

One measure of the extent to which phase change material 202 is melted in order to amorphize sufficient material to RESET the cell of FIG. 3A is the diameter of the programmed volume TH_{MELT}. As indicated in the graph of FIG. 3D, the volume of phase change material that is melted is greater than that required to RESET the cell (that volume corresponding to the thickness TH_{SAT}). This difference may be used as one metric in illustrating the effectiveness of focusing power dissipation in a preferred region of phase change material. As will be described in greater detail in the discussions related to FIGS. 4A-4D, and 5A-5D, a modified-resistivity programmable resistance memory in accordance with the principles of the present invention, focuses more power to a critical program volume, thereby reducing the amount of power dissipated in heating and/or melting phase change material that does not contribute to the transformation of the memory cell to the RESET state.

FIGS. 4A, 4B, 4C, and 4D are graphical illustrations, respectively, of an amorphization profile of an illustrative embodiment of a confined-cell phase change memory in accordance with the principles of the present invention, of the corresponding variable resistivity and/or variable melting temperature of phase change material within the pore 204, of the corresponding power dissipation during programming of phase change material 202 within the pore 204, and of the corresponding temperature within the pore 204. In this illustrative embodiment the cell has been programmed to the RESET state by raising the temperature of a volume of phase change material to the melting temperature Tm (Tm′ in a modified melting temperature embodiment) of the phase change material and cooling the melted material rapidly to thereby quench the material in the amorphous state. In this illustrative embodiment, as in the embodiment illustrated in FIGS. 3A-3D, the volume of material thus-transformed is referred to as the programmed volume 300. Also as in the embodiment illustrated in FIGS. 3A-3D, the programmed volume 300 exhibits a profile that includes a minimal vertical thickness TH_{SAT}, which ensures that the resistance of the phase change cell, as measured between the two contacts, TEC and BEC, equals or exceeds the saturation resistance of the cell.

However, in this illustrative embodiment, the volume of material within the programmed volume is substantially less than that required in the conventional embodiment of FIG. 3A. The reason for this reduction in programmed volume (and concomitant reduction in dissipated power) can be seen by reference to the resistivity profile of FIG. 4B. The resistivity profile of FIG. 4B illustrates the SET resistivity of the phase change material 202. In this embodiment, unlike that of FIGS. 3A-3D in which all the phase-change material exhibited the same SET resistivity, the resistivity of the phase change material is greater at a distance from the top and bottom electrode contacts TEC, BEC. In this illustrative embodiment, the resistivity distribution of the phase change material exhibits a substantially Gaussian distribution, with a peak location coincident with the center of the programmed volume (that is, equidistant from TEC and BEC).

In accordance with the principles of the present invention, the location of the peak resistivity is chosen to coincide with the location of the greatest vertical thermal isolation. In this way, a phase change memory cell in accordance with the principles of the present invention increases power dissipation in a region where the power will be most effectively utilized to melt and amorphize the phase change material, as illustrated in the power dissipation graphical representation of FIG. 4C. Because the resistivity profile of the phase-change material steadily increases with distance from an electrode contact, power generation (in the form of Joule heating, i²R) also increases with distance from either electrode contact, as indicated by the Gaussian curve of FIG. 4C. Because power generation in the phase change material peaks in a location removed from either electrode contact, phase change material in the peak region of power generation also reaches higher temperatures, for a given current, than phase change material outside the region of peak resistivity, as indicated by the temperature profile of FIG. 4D. In short, in a programmable resistance cell in accordance with the principles of the present invention, the greatest power is generated in a region within the phase change material where it is more likely to be utilized in melting and amorphizing the phase change material, rather than being channeled away through a low thermal resistance path.

Similarly, in a modified-melting temperature embodiment, the volume of material within the programmed volume is substantially less than that required in the conventional embodiment of FIG. 3A. The reason for this reduction in programmed volume (and concomitant reduction in dissipated power) can be seen by reference to the melting temperature profile of FIG. 4B (broken line labeled Tm′). The melting temperature profile of FIG. 4B illustrates the SET melting temperature of the phase change material 202. In this embodiment, unlike that of FIGS. 3A-3D in which all the phase-change material exhibited the same SET melting temperature, the melting temperature of the phase change material is lower at a distance from the top and bottom electrode contacts TEC, BEC. In this illustrative embodiment, the melting temperature distribution of the phase change material exhibits a substantially negative Gaussian distribution, with a minimum located coincident with the center of the programmed volume (that is, equidistant from TEC and BEC).

In accordance with the principles of the present invention, the location of the minimal melting temperature is chosen to coincide with the location of the greatest vertical thermal isolation. In this way, a phase change memory cell in accordance with the principles of the present invention increases the propensity for melting in a region where the power will be most effectively utilized to melt and amorphize the phase change material. Because the melting temperature of the phase-change material steadily decreases with distance from an electrode contact, the volume of phase change material that reaches the modified melting temperature Tm′ steadily increases with distance from either electrode contact, as indicated by the temperature profile of FIG. 4D. In short, in a programmable resistance cell in accordance with the principles of the present invention, the greatest power may be generated in a region within the phase change material where it is more likely to be utilized in melting and amorphizing the phase change material, rather than being channeled away through a low thermal resistance path. Additionally, with a modified melting temperature profile, a greater volume of material may be amorphized in a region of enhanced phase change for a given power dissipation.

FIGS. 5A, 5B, 5C, and 5D are graphical illustrations, respectively, of an amorphization profile of an illustrative embodiment of a confined-cell phase change memory in accordance with the principles of the present invention, of the corresponding resistivity of phase change material within the pore 204, of the corresponding power dissipation during programming of phase change material 202 within the pore 204, and of the corresponding temperature within the pore 204. In this illustrative embodiment the cell has been programmed to the RESET state by raising the temperature of a volume of phase change material to the melting temperature Tm of the phase change material and cooling the melted material rapidly to thereby quench the material in the amorphous state. In this illustrative embodiment, as in the embodiment illustrated in FIGS. 3A-3D, the volume of material thus-transformed is referred to as the programmed volume 300. Also as in the embodiment illustrated in FIGS. 3A-3D, the programmed volume 300 exhibits a profile that includes a minimal vertical thickness TH_{SAT}, which ensures that the resistance of the phase change cell, as measured between the two contacts, TEC and BEC, equals or exceeds the saturation resistance of the cell.

In this illustrative embodiment, the volume of amorphized material in the programmed volume required to achieve the saturation resistance is substantially less than that required in the conventional embodiment of FIG. 3A. The reason for this can be seen by reference to the resistivity profile of FIG. 5B. The resistivity profile of FIG. 5B illustrates the SET resistivity of the phase change material 202. In this embodiment, unlike that of FIGS. 3A-3D in which all the phase-change material exhibited the same SET resistivity, the resistivity of the phase change material is greater at a distance from the top and bottom electrode contacts TEC, BEC. In this illustrative embodiment, the resistivity distribution of the phase change material exhibits a step increase in resistivity approximately equidistant from the top and bottom electrode contacts. Such a step increase in resistivity may be produced by sequential deposition of a layer of “base” phase change material, a layer of high resistivity phase change material centered equidistant from the top and bottom electrode contacts TEC, BEC, and another layer of “base” phase change material. The high resistivity phase change material may be chosen from: the GeSbTe alloy system, the Ag and/or In doped SbTe eutectic system, the Ge and/or Sn doped SbTe eutectic system, the InSbTe alloy system, the GaSbTe alloy system, the GaSb alloy system, or the GeSb alloy system, for example, and the thickness of the layer may be chosen to be substantially equal to the thickness TH_{SAT} which dictates the saturation resistance of the memory cell. The resistivity of the high-resistivity material may be in the range of 200% to 10,000% the resistivity of the “base” phase change material. In a preferred embodiment, the resistivity of the high-resistivity material may be in the range of 500% to 5000% the resistivity of the “base” phase change material. In a still more preferred embodiment, the resistivity of the high-resistivity material may be in the range of 500% to 1000% the resistivity of the “base” phase change material. The melting temperature Tm′ of the low melting temperature material may be in the range of 30% to 95% the melting temperature Tm of the “base” phase change material (in Celsius). In a preferred embodiment, the melting temperature of the low melting temperature material may be in the range of 50% to 75% the melting temperature of the “base” phase change material(in Celsius). In a still more preferred embodiment, the melting temperature of the low melting temperature material may be in the range of 60% to 70% the melting temperature of the “base” phase change material(in Celsius).

As with the embodiment described in the discussion related to FIGS. 4A-4D, in accordance with the principles of the present invention, the location of the step increase in resistivity is chosen to coincide with the location of the greatest vertical thermal isolation. In this way, a phase change memory cell in accordance with the principles of the present invention increases power dissipation in a region where the power will be most effectively utilized to melt and amorphize the phase change material, as illustrated in the power dissipation graphical representation of FIG. 5C.

Because the resistivity profile of the phase-change material abruptly increases at a distance from either electrode contact, power generation (in the form of Joule heating, i²R) also abruptly increases at a distance from either electrode contact. This is reflected in the step-increase of the curve of FIG. 5C. Because power generation in the phase change material is maximized in a location removed from either electrode contact, phase change material in this maximized region of power generation also reaches higher temperatures, for a given current, than phase change material outside the region of peak resistivity, as indicated by the temperature profile of FIG. 5D. Combinations of stepped and graded resistivity profiles, such as may be obtained by combinations of the profile of FIGS. 4B with the profile of FIGS. 5B, for example, are also contemplated within the scope of the invention.

A programmable resistance memory cell having an Gaussian SET resistivity profile in accordance with the principles of the present invention (such as that of FIG. 4B, for example) may be produced, for example, by implantation of N₂⁺ ions, N⁺ ions, O⁺ ions, O₂⁺ ions, or Si⁺ ions in a phase change material such as GST225. In accordance with the principles of the present invention, the incident energy of the ions may be chosen so that the projected ion range is half the height of the phase change alloy cylinder. Additionally, the implantation dose may be chosen so that at the peak of the implant distribution, the concentration of the implanted ions is between about 5% and 10%, yielding an increase in resistivity of one- to two-orders of magnitude in the peak region. Implantation of phase change material to alter the resistivity of phase change materials is known and discussed, for example, in, “Effects of N₂⁺ Implantation on Phase Transition in Ge₂Sb₂Te₂ Films,” by Y. K Kim et al, in the Journal of Applied Physics 100, 083502 (2006) and in, “Effect of N-Implantation on the Structural and Electrical Characteristics of Ge₂Sb₂Te₂ Phase Change Film,” Bo Liu, et al, in Thin Solid Films 478 (2005) 49-55, which are hereby incorporated by reference. In these illustrative implantation examples, the incorporated nitrogen is reported to reduce the Ge₂Sb₂Te₂'s crystallite size and to inhibit the transformation of the material's face-centered-cubic (FCC) phase to the hexagonal close-packed (HCP) phase at elevated temperature. Both the reduced crystallite size, which results in a large number of grain boundaries, and the higher resistivity thermally stable FCC phase of the phase change material tend to increase the resistivity of the Ge₂Sb₂Te₂ (also referred to herein as GST225). In accordance with the principles of the present invention, the implantation may be performed after the pore 206 is filled with phase change material 204, but before the top contact TEC is deposited and patterned. In accordance with the principles of the present invention, angled implantations and/or a plurality of implantations may be carried out. Such implantations may be employed to produce resistivity profiles that further reduce required programming current by isolating a programmed volume from paths of high thermal conductivity.

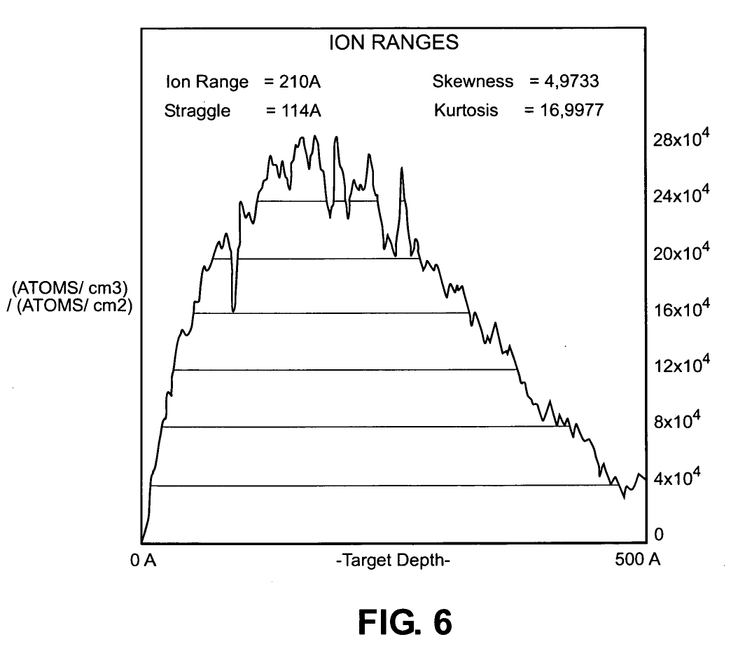

The ion implantation profile of FIG. 6 provides an illustration of N₂⁺ ion concentration in implanted Ge₂Sb₂Te₂ as a function of vertical distance from the Ge₂Sb₂Te₂/TEC interface. This distribution was simulated using the SRIM 2003 ion implantation program with a 500 Angstrom tall Ge₂Sb₂Te₂ alloy cylinder and 15 keV incident ion energy. An implantation dose of 5E15 cm⁻² to 2E16 cm⁻² can achieve the desired nitrogen concentration, depending on the height of the phase change alloy cylinder and the incident energy of the ions. The exact dose and incident energy can be calculated for a specific device using, for example, the SRIM 2003 ion implantation program, available at http://www.srim.org.

Similarly, a programmable resistance memory cell in accordance with the principles of the present invention with a “negative Guassian” profile may be produced, for example, by implantation in a phase change material such as GST225. In accordance with the principles of the present invention, the incident energy of the ions may be chosen so that the projected ion range is half the height of the phase change alloy cylinder. Additionally, the implantation dose may be chosen so that at the peak of the implant distribution, the concentration of the implanted ions is between about 5% and 10%, yielding a decrease in melting temperature of 50% to 75% in the peak implant, minimal melting temperature, region.

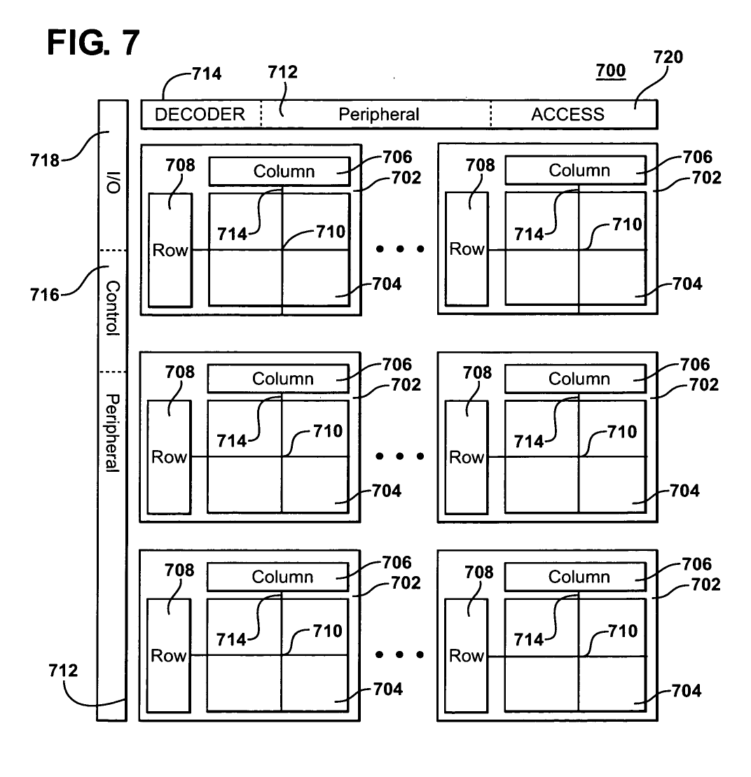

The conceptual block diagram of FIG. 7 provides a functional level view of an illustrative embodiment of a programmable resistance memory circuit 700 in accordance with the principles of the present invention. In this illustrative embodiment, a programmable resistance memory 700 includes at least one array of programmable resistance memory cells arranged as a storage matrix tile 702, along with peripheral circuitry that, in combination, yields the programmable resistance memory circuit 700. As described in greater detail in the discussion related to FIGS. 4A through 6, the programmable resistance memory cells of the storage matrix 704 may be implemented as, for example, phase change memory cells having regions of high SET resistivity. In this illustrative embodiment, the memory circuit 700 includes row drivers 708 and column drivers 706 configured to access cells within the storage matrix 704.

Accesses carried out by the row 708 and column 706 drivers include reading from the memory cells of the matrix 704 and writing to the memory cells of the matrix 704. Peripheral circuitry 712 includes decoding circuitry 714 which accepts address signals and decodes the address signals to determine which of the row 708 and column 706 drivers to activate and, thereby, which of the memory cells within the array 704 to access.

Peripheral circuitry 712 may include control circuitry 716 that accepts READ, WRITE, and CLOCK signals and develops control signals for the memory 700. The control signals developed for the memory 700 may include data direction control (e.g., “read from” or “write to” the storage matrix tile 702) and clock signals, for example. The input/output circuitry 718 includes circuitry configured to accept data for writing to and to drive data read from the storage matrix tile 702.

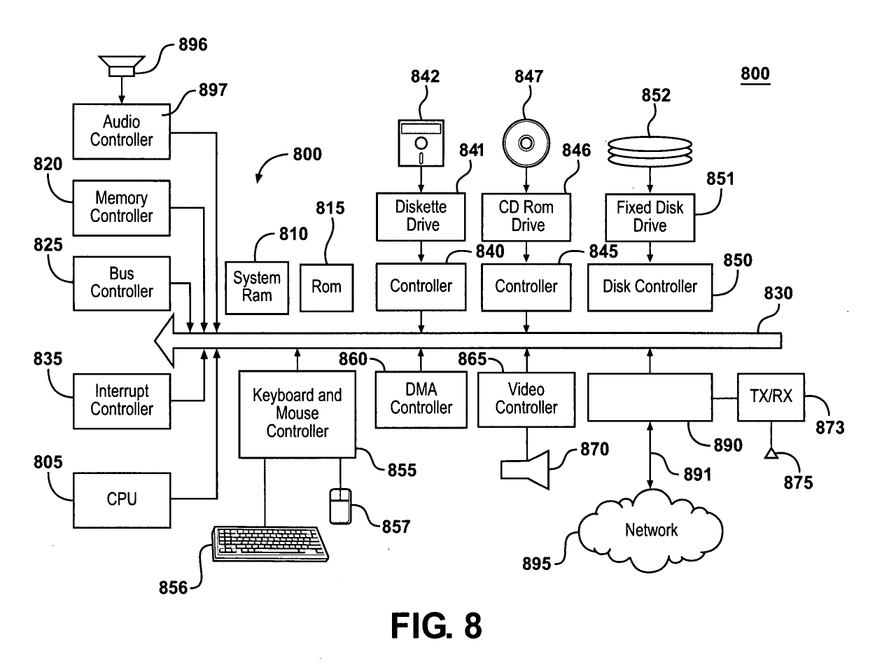

The programmable resistance devices described in the discussion related to the previous figures may be employed to particular advantage in a wide variety of systems. The schematic diagram of FIG. 8 will be discussed to illustrate the devices' use in a few such systems. The schematic diagram of FIG. 8 includes many components and devices, some of which may be used for specific embodiments of a system in accordance with the principles of the present invention and while others not used. In other embodiments, other similar systems, components and devices may be employed. In general, the system includes logic circuitry configured to operate along with programmable resistance memory which may include phase change memory. The logic circuitry may be discrete, programmable, application-specific, or in the form of a microprocessor, microcontroller, or digital signal processor, for example. In some embodiments, the logic circuitry may be implemented using thin film logic. And the embodiments herein may also be employed on integrated chips or connected to such circuitry. The exemplary system of FIG. 8 is for descriptive purposes only. Although the description may refer to terms commonly used in describing particular computer, communications, tracking, and entertainment systems; the description and concepts equally apply to other systems, including systems having architectures dissimilar to that illustrated in FIG. 8. The electronic system 800, in various embodiments, may be implemented as, for example, a general purpose computer, a router, a large-scale data storage system, a portable computer, a personal digital assistant, a cellular telephone, an electronic entertainment device, such as a music or video playback device or electronic game, a microprocessor, a microcontroller, a digital signal processor, or a radio frequency identification device. Any or all of the components depicted in FIG. 8 may employ a memory or a chalcogenide electronic device, such as a chalcogenide-based nonvolatile memory and/or threshold switch, for example. In an illustrative embodiment, the system 800 may include a central processing unit (CPU) 805, which may be implemented with some or all of a microprocessor, a random access memory (RAM) 810 for temporary storage of information, and a read only memory (ROM) 815 for permanent storage of information. A memory controller 820 is provided for controlling RAM 810. In accordance with the principles of the present invention, all of, or any portion of, any of the memory elements (e.g. RAM or ROM) may be implemented as a standalone thin film memory which may include chalcogenide-based nonvolatile memory.

An electronic system 800 in accordance with the principles of the present invention may be a microprocessor that operates as a CPU 805, in combination with embedded chalcogenide-based electronic nonvolatile memory that operates as RAM 810 and/or ROM 815, or as a portion thereof. In this illustrative example, the microprocessor/chalcogenide-nonvolatile memory combination may be standalone, or may operate with other components, such as those of FIG. 8 yet-to-be described.

In implementations within the scope of the invention, a bus 830 interconnects the components of the system 800. A bus controller 825 is provided for controlling bus 830. An interrupt controller 835 may or may not be used for receiving and processing various interrupt signals from the system components. Such components as the bus 830, bus controller 825, and interrupt controller 835 may be employed in a large-scale implementation of a system in accordance with the principles of the present invention, such as that of a computer, a router, a portable computer, or a data storage system, for example.

Mass storage may be provided by diskette 842, CD ROM 847, or hard drive 852. Data and software may be exchanged with the system 800 via removable media such as diskette 842 and CD ROM 847. Diskette 842 is insertable into diskette drive 841 which is, in turn, connected to bus 830 by a controller 840. Similarly, CD ROM 847 is insertable into CD ROM drive 846 which is, in turn, connected to bus 830 by controller 845. Hard disc 852 is part of a fixed disc drive 851 which is connected to bus 830 by controller 850. Although conventional terms for storage devices (e.g., diskette) are being employed in this description of a system in accordance with the principles of the present invention, any or all of the storage devices may be implemented using a memory which may include chalcogenide-based nonvolatile memory in accordance with the principles of the present invention. Removable storage may be provided by a nonvolatile storage component, such as a thumb drive, that employs a chalcogenide-based nonvolatile memory in accordance with the principles of the present invention as the storage medium. Storage systems that employ chalcogenide-based nonvolatile memory as “plug and play” substitutes for conventional removable memory, such as disks or CD ROMs or thumb drives, for example, may emulate existing controllers to provide a transparent interface for controllers such as controllers 840, 845, and 850, for example.

User input to the system 800 may be provided by any of a number of devices. For example, a keyboard 856 and mouse 857 are connected to bus 830 by controller 855. An audio transducer 896, which may act as both a microphone and/or a speaker, is connected to bus 830 by audio controller 897, as illustrated. Other input devices, such as a pen and/or tabloid may be connected to bus 830 and an appropriate controller and software, as required, for use as input devices. DMA controller 860 is provided for performing direct memory access to RAM 810, which, as previously described, may be implemented in whole or part using chalcogenide-based nonvolatile memory devices in accordance with the principles of the present invention. A visual display is generated by video controller 865 which controls display 870. The display 870 may be of any size or technology appropriate for a given application.

In a cellular telephone or portable entertainment system embodiment, for example, the display 870 may include one or more relatively small (e.g. on the order of a few inches per side) LCD displays. In a large-scale data storage system, the display may be implemented as large-scale multi-screen, liquid crystal displays (LCDs), or organic light emitting diodes (OLEDs), including quantum dot OLEDs, for example.

The system 800 may also include a communications adaptor 890 which allows the system to be interconnected to a local area network (LAN) or a wide area network (WAN), schematically illustrated by bus 891 and network 895. An input interface 899 operates in conjunction with an input device 893 to permit a user to send information, whether command and control, data, or other types of information, to the system 800. The input device and interface may be any of a number of common interface devices, such as a joystick, a touch-pad, a touch-screen, a speech-recognition device, or other known input device. In some embodiments of a system in accordance with the principles of the present invention, the adapter 890 may operate with transceiver 873 and antenna 875 to provide wireless communications, for example, in cellular telephone, RFID, and wifi computer implementations.

Operation of system 800 is generally controlled and coordinated by operating system software. The operating system controls allocation of system resources and performs tasks such as processing scheduling, memory management, networking, and I/O services, among other things. In particular, an operating system resident in system memory and running on CPU 805 coordinates the operation of the other elements of the system 800.

In illustrative handheld electronic device embodiments of a system 800 in accordance with the principles of the present invention, such as a cellular telephone, a personal digital assistance, a digital organizer, a laptop computer, a handheld information device, a handheld entertainment device such as a device that plays music and/or video, small-scale input devices, such as keypads, function keys and soft keys, such as are known in the art, may be substituted for the controller 855, keyboard 856 and mouse 857, for example. Embodiments with a transmitter, recording capability, etc., may also include a microphone input (not shown).

In an illustrative RFID transponder implementation of a system 800 in accordance with the principles of the present invention, the antenna 875 may be configured to intercept an interrogation signal from a base station at a frequency F₁. The intercepted interrogation signal would then be conducted to a tuning circuit (not shown) that accepts signal F₁ and rejects all others. The signal then passes to the transceiver 873 where the modulations of the carrier F₁ comprising the interrogation signal are detected, amplified and shaped in known fashion. The detected interrogation signal then passes to a decoder and logic circuit which may be implemented as discrete logic in a low power application, for example, or as a microprocessor/memory combination as previously described. The interrogation signal modulations may define a code to either read data out from or write data into a chalcogenide-based nonvolatile memory in accordance with the principles of the present invention. In this illustrative embodiment, data read out from the memory is transferred to the transceiver 873 as an “answerback” signal on the antenna 875 at a second carrier frequency F₂. In passive RFID systems, power is derived from the interrogating signal and memory such as provided by a chalcogenide-based nonvolatile memory in accordance with the principles of the present invention is particularly well suited to such use.

I claim:

1. A memory cell, comprising:
a volume of programmable resistance material that includes a minimal resistance state;
a first electrode coupled to the volume of programmable resistance material; and
a second electrode coupled to the volume of programmable resistance material, wherein the programmable resistance material exhibits a region of enhanced programmability at a distance from both electrodes.

2. The memory cell of claim 1 wherein the region of enhanced programmability is positioned substantially midway between the electrodes.

3. The memory cell of claim 1 wherein the cell is a confined cell.

4. The memory cell of claim 3 wherein the volume of programmable resistance material is substantially confined within a pore formed in dielectric material.

5. The memory cell of claim 1 wherein the region of enhanced programmability includes a region in which the programmable resistance material exhibits a resistivity profile that, in its minimal resistance state, includes a maximum in resistivity.

6. The memory cell of claim 1 wherein the region of enhanced programmability includes a region in which the programmable resistance material exhibits a melting temperature profile that, in the material's minimum resistance state, includes a melting temperature minimum.

7. The memory cell of claim 3 wherein the programmable resistance material is a phase change memory material.

8. The memory cell of claim 7 wherein the phase-change memory material is a chalcogenide material.

9. The memory cell of claim 5 wherein the programmable resistance material includes implanted ions that yield the variable un-programmed electrical resistance maximum.

10. The memory cell of claim 6 wherein the programmable resistance material includes implanted ions that yield the variable un-programmed melting temperature minimum.

11. The memory cell of claim 9 wherein the implanted ions exhibit a concentration distribution with a peak between about 1% and 40%.

12. The memory cell of claim 10 wherein the implanted ions exhibit a concentration distribution with a peak between about 1% and 40%.

13. The memory cell of claim 11 wherein the implanted ions exhibit a concentration distribution with a peak between about 5% and 10%.

14. The memory cell of claim 12 wherein the implanted ions exhibit a concentration distribution with a peak between about 5% and 10%.

15. A memory cell, comprising:
a volume of programmable resistance material that includes a minimal resistance state;
a first electrode coupled to the volume of programmable resistance material; and
a second electrode coupled to the volume of programmable resistance material, wherein the programmable resistance material exhibits a melting temperature profile that, in the cell's minimal resistance state, includes a minimum melting temperature at a distance from both electrodes.

16. The memory cell of claim 15 wherein the region of minimal melting temperature is positioned substantially midway between the electrodes.

17. The memory cell of claim 15 wherein the cell is a confined cell.

18. The memory cell of claim 17 wherein the volume of programmable resistance material is substantially confined within a pore formed in dielectric material.

19. The memory cell of claim 15 wherein the programmable resistance material is a phase change memory material.

20. The memory cell of claim 19 wherein the phase-change memory material is a chalcogenide material.

21. The memory cell of claim 15 wherein the programmable resistance material includes implanted ions that yield the variable un-programmed melting temperature minimum.

22. The memory cell of claim 15 wherein the programmable resistance material exhibits a resistivity profile that, in the cell's minimal resistance state, includes a maximum resistivity at a distance.

23. A memory cell, comprising:
a volume of programmable resistance material that includes a minimal resistance state;
a first electrode coupled to the volume of programmable resistance material; and
a second electrode coupled to the volume of programmable resistance material, wherein the programmable resistance material exhibits a resistivity profile that, in the cell's minimal resistance state, includes a maximum resistivity at a distance from both electrodes.

24. The memory cell of claim 23 wherein the region of maximum resistivity is positioned substantially midway between the electrodes.

25. The memory cell of claim 23 wherein the cell is a confined cell.

26. The memory cell of claim 25 wherein the volume of programmable resistance material is substantially confined within a pore formed in dielectric material.

27. The memory cell of claim 23 wherein the programmable resistance material is a phase change memory material.

28. The memory cell of claim 27 wherein the phase-change memory material is a chalcogenide material.

29. The memory cell of claim 23 wherein the programmable resistance material includes implanted ions that yield the variable un-programmed resistivity maximum.

30. The memory cell of claim 23 wherein the programmable resistance material exhibits a melting temperature profile that, in the cell's minimal resistance state, includes a minimum melting temperature at a distance from both electrodes.

31. An electronic device, comprising:
an array of memory cells, each cell including:
a volume of programmable resistance material;
a first electrode coupled to the volume of programmable resistance material;
a second electrode coupled to the volume of programmable resistance material, the combination thereby forming a volume of programmable resistance material formed between and coupled to first and second electrodes, wherein the volume of programmable resistance material includes a volume of programmable resistance material configured to preferentially reset; and
a microprocessor configured to access the memory array.

32. The electronic device of claim 31 wherein the volume of programmable resistance material configured to preferentially reset within each memory cell is positioned at a distance from both electrodes in the cell.

33. The electronic device of claim 32 wherein, within each cell, a portion of the programmable resistance material exhibits higher electrical resistance than the remainder of the programmable resistance material, thereby forming a volume of programmable resistance material that is preferentially reset.

34. The electronic device of claim 32 wherein, within each cell, a portion of the programmable resistance material exhibits lower melting temperature than the remainder of the programmable resistance material, thereby forming a volume of programmable resistance material that is preferentially reset.

35. The electronic device of claim 33 wherein, within each cell, a portion of the programmable resistance material exhibits lower melting temperature than the remainder of the programmable resistance material, portions having lower melting temperature and higher resistivity substantially overlapping to form a volume of programmable resistance material that is preferentially reset.

36. The electronic device of claim 35 wherein, within each cell, the peak in electrical resistance is positioned to optimize the thermal resistance of material surrounding the peak in electrical resistance.

37. The electronic device of claim 35 wherein, within each cell, the peak in the electrical resistance profile is positioned substantially midway between the electrodes.

38. The electronic device of claim 37 further comprising a transmitter/receiver configured to transmit data from and receive data for the microprocessor.

39. The electronic device of claim 38 wherein the memory, microprocessor and transmitter/receiver are configured as a cellular telephone.

40. The electronic device of claim 39 wherein the memory and microprocessor are configured as a handheld entertainment device.

41. The electronic device of claim 39 wherein the memory and microprocessor are configured as a solid state drive (SSD).

42. A method comprising the steps of:
providing a substrate;
forming an electrode on the substrate;
forming a volume of programmable resistance material on the electrode;
modifying the programmable resistance material to form a volume of material that preferentially resets; and
forming an electrode on the programmable resistance material.

43. The method of claim 42 wherein the volume of programmable resistance material configured to preferentially reset is positioned at a distance from both electrodes.

44. The method of claim 42 wherein the step of forming a volume of programmable resistance material that preferentially resets includes the step of forming a portion of the programmable resistance material that exhibits higher electrical resistance than the remainder of the programmable resistance material.

45. The method of claim 42 wherein the step of forming a volume of programmable resistance material that preferentially resets includes the step of forming a portion of the programmable resistance material that exhibits a lower melting temperature than the remainder of the programmable resistance material.

46. The method of claim 45 including the step of forming a region of continuously-variable electrical resistance that exhibits a peak in a location at a distance from either electrode.
